(19) United States
(12) Patent Application Publication
(10) Pub. No.: US 2017/0133284 A1
(43) Pub. Date: May 11, 2017

(54) SMART IN-SITU CHAMBER CLEAN

(71) Applicant: Texas Instruments Incorporated, Dallas, TX (US)

(72) Inventor: John Christopher Shriner, Allen, TX (US)

(73) Assignee: TEXAS INSTRUMENTS INCORPORATED, Dallas, TX (US)

(21) Appl. No.: 14/934,113

(22) Filed: Nov. 5, 2015

(51) Int. Cl. H01L 21/66

(52) U.S. Cl. CPC H01L 22/24

(57) ABSTRACT

A microelectronic device is formed using a fabrication tool such as a plasma thin film deposition tool or a plasma etch tool. A smart in-situ chamber clean begins with an initial plasma. A first physical signal is measured while the initial plasma is in progress, and the measured value is stored in a memory unit. A process controller retrieves the measured value, uses it to compute a deposition estimate parameter, and determines when the deposition estimate parameter meets a minimum deposition criterion. When the result of the determination is TRUE, the smart in-situ chamber clean terminates without an in-situ cleaning of the process chamber. When the result of the determination is FALSE, the smart in-situ chamber clean proceeds with an in-situ cleaning. The in-situ cleaning may be a continuation of the initial plasma. Subsequently, the microelectronic device is processed in the fabrication tool.

### FIELD OF THE INVENTION

This invention relates to the field of microelectronic devices. More particularly, this invention relates to methods of forming microelectronic devices.

### BACKGROUND OF THE INVENTION

Many plasma etch and deposition tools for microelectronic device fabrication use in-situ chamber cleans in order to remove the process deposition to allow the chamber to perform with low particle contamination. But when the in-situ chamber cleans are run with excessive times (required to ensure all deposition has been removed) when the chamber has little to no deposition, many times there are secondary by-products that are formed which contribute to excess particle contamination. Endpointed in-situ chamber cleans often run excessive clean times when the chamber has little to no deposition, due to the difficulty of determining the endpoint condition.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to a more detailed description that is presented later.

A microelectronic device is formed using a fabrication tool with a process chamber. A smart in-situ chamber clean is performed which begins with an initial plasma step. A first physical signal is measured while the initial plasma step is in progress. The measured value of the first physical signal is stored in a memory unit. A process controller retrieves the measured value of the first physical signal and uses it to compute a deposition estimate parameter. The process controller determines when the deposition estimate parameter meets a minimum deposition criterion. When the result of the determination is TRUE, the smart in-situ chamber clean terminates without further cleaning of the process chamber. When the result of the determination is FALSE, the smart in-situ chamber clean proceeds with an in-situ cleaning of the process chamber. Subsequently, the microelectronic device is processed in the fabrication tool.

### DESCRIPTION OF THE VIEWS OF THE DRAWING

FIG. 1A through FIG. 1C are views of a fabrication tool used for formation of a microelectronic device, depicted in successive stages of an example fabrication sequence.

FIG. 2A through FIG. 2E are views of the fabrication tool of FIG. 1A through FIG. 1C, depicted in successive stages of another example fabrication sequence used for formation of the microelectronic device.

FIG. 3 is a flowchart of the smart in-situ chamber clean process.

### DETAILED DESCRIPTION OF EXAMPLE EMBODIMENTS

The present invention is described with reference to the attached figures. The figures are not drawn to scale and they are provided merely to illustrate the invention. Several aspects of the invention are described below with reference to example applications for illustration. It should be understood that numerous specific details, relationships, and methods are set forth to provide an understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

A microelectronic device is formed using a fabrication tool with a process chamber. Examples of fabrication tools are plasma etch tools and thin film deposition tools. A smart in-situ chamber clean is performed which begins with forming an initial plasma. The initial plasma has a short time duration so as to generate minimal secondary deposition. A first physical signal is measured while the initial plasma step is in progress. Examples of physical signals are optical emission signals, infrared absorption signals, residual gas analysis signals, and spectral reflectometry signals, possibly generated in the initial plasma and possibly generated in a downstream plasma generator. The measured value of the first physical signal is stored in a memory unit. A process controller, such as a computer connected to the fabrication tool, retrieves the measured value of the first physical signal and uses it to compute a deposition estimate parameter, which provides a value of how much unwanted deposition exists in the process chamber. The process controller determines when the deposition estimate parameter meets a minimum deposition criterion. When the result of the determination is TRUE, the smart in-situ chamber clean terminates without further cleaning of the process chamber to avoid unnecessary secondary deposition. When the result of the determination is FALSE, the smart in-situ chamber clean proceeds with an in-situ cleaning of the process chamber. The in-situ cleaning may be endpointed, may have overetch, or may run for a fixed time. Subsequently, the microelectronic device is processed in the fabrication tool.

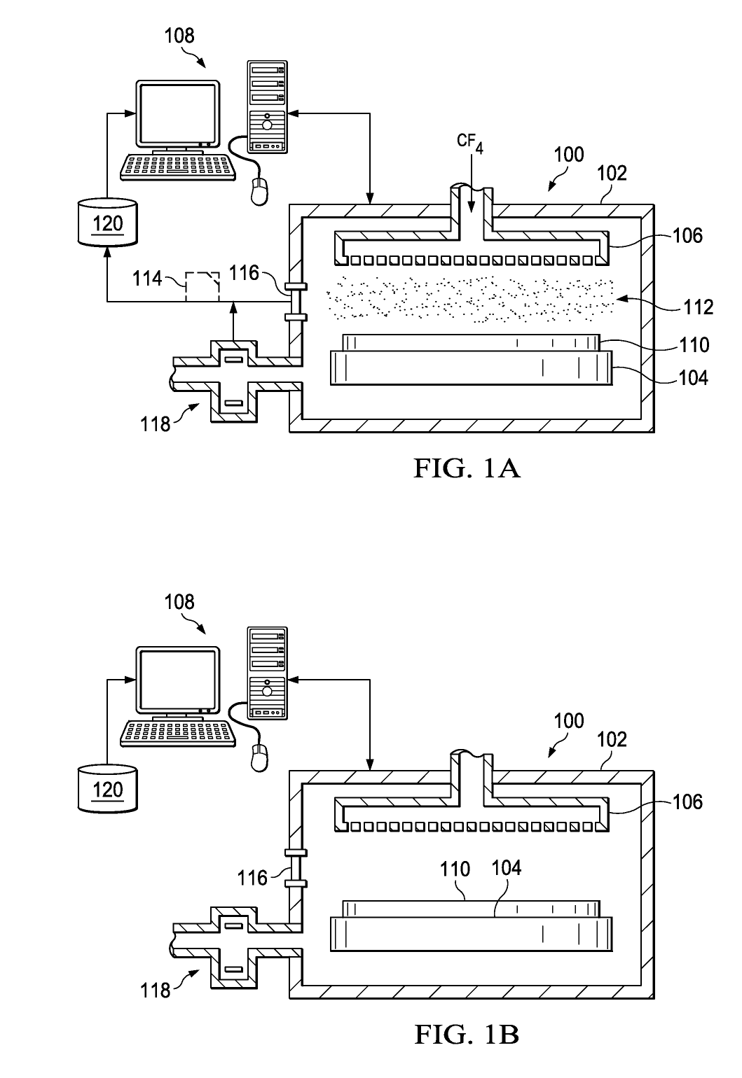

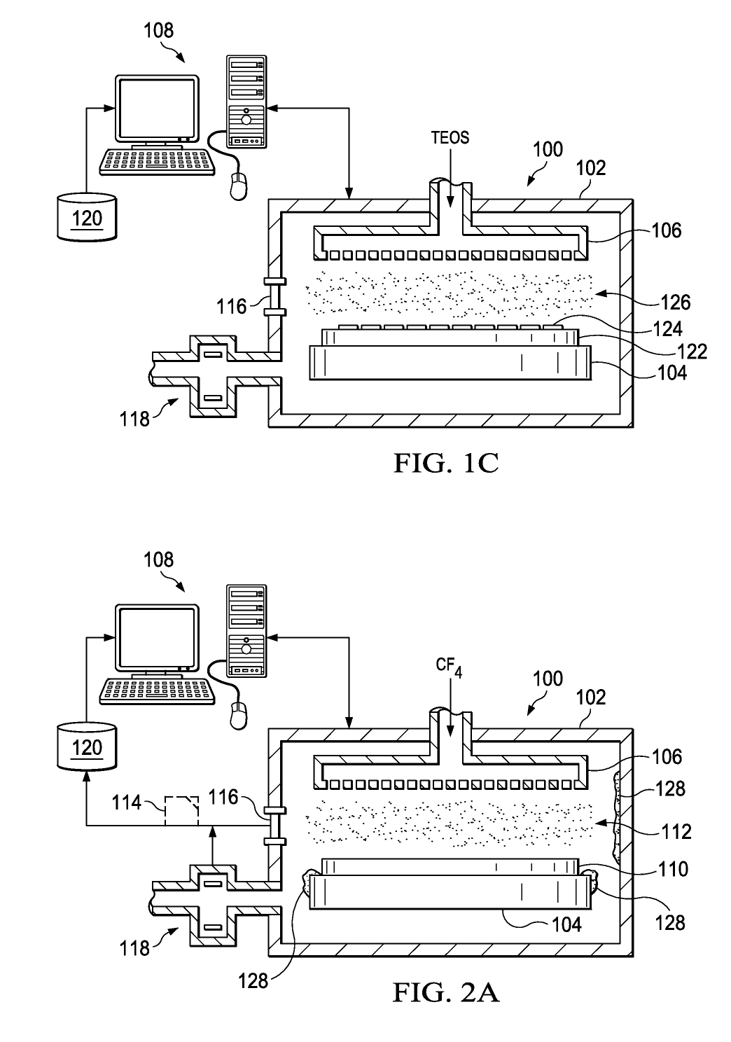

FIG. 1A through FIG. 1C are views of a fabrication tool used for formation of a microelectronic device, depicted in successive stages of an example fabrication sequence. Referring to FIG. 1A, the fabrication tool 100 includes a process chamber 102. In the instant example, the process chamber 102 encloses a wafer chuck 104 and an upper electrode 106 which may be a gas delivery manifold such as a showerhead, as depicted in FIG. 1A. Other configurations of the fabrication tool 100 are within the scope of the instant example.

A process controller 108 is coupled to the fabrication tool 100. The process controller 108 may be, for example, a standalone computer, a networked computer, a state machine, or a customized system configured for the fabrication tool 100. The process controller 108 may be a single system or may comprise a plurality of systems coupled together. The process controller 108 may be dedicated to the fabrication tool 100 or may be coupled to other fabrications tools as well as the fabrication tool 100.

FIG. 1A depicts a first step in a smart in-situ camber clean process, an initial check for deposition. A dummy wafer 110 is placed in the fabrication tool 100 on the wafer chuck 104. A first reactant gas, for example a fluorinated gas such as CF4 as depicted in FIG. 1A, is flowed to a plasma region over the dummy wafer 110, for example through the upper electrode 106 as depicted in FIG. 1A. Other reactant gases may be flowed to the plasma region. An initial plasma 112 is formed from the first reactant gas over the dummy wafer 110. The initial plasma 112 may remove a portion of unwanted deposited material, if present, in the process chamber 102.

While the initial plasma 112 is in progress, a measured value 114 of a first physical signal is obtained. The first physical signal may be, for example, an optical emission signal from the initial plasma 112 through a window 116 in the process chamber 102, an infrared absorption signal through the window 116, a spectral reflectometry signal through the window 116, or an optical emission signal, an infrared absorption signal or a spectral reflectometry signal from a downstream plasma generator 118. Other examples of the first physical signal are residual gas analysis of exhaust gases from the initial plasma 112, voltage measurements such as bias voltage or peak-to-peak voltage from applied bias power to the upper electrode 106 and/or the wafer chuck 104, throttle valve angle as a constant pressure is maintained in the process chamber 102, match capacitor and/or inductor value used to maintain a power level to the initial plasma 112, a backside helium flow to the wafer chuck 104, and a temperature of the wafer chuck 104. The measured value 114 of the first physical signal is stored in a memory unit 120, such as a memory storage device of the process controller 108. In some versions of the instant example, more than one measured value 114 of the first physical signal may be obtained at different times and stored in the memory unit 120. In other versions, one or more measured values 114 of other physical signals may be obtained and stored in the memory unit 120. The initial plasma 112 is maintained long enough to obtain a desired set of the measured values 114. In some versions of the instant example, the initial plasma 112 may be maintained for a few seconds to less than one minute. In other versions, the initial plasma 112 may be maintained for several minutes.

The measured value 114 of the first physical signal is retrieved from the memory unit 120 and transferred to the process controller 108. Additional measured values 114 of the first physical signal or other physical signals, if stored in the memory unit 120, may also be retrieved and transferred to the process controller 108. The process controller 108 uses the retrieved measured values 114 to compute a deposition estimate parameter which provides a value of how much unwanted deposited material exists in the process chamber 102. Computation of the deposition estimate parameter may involve, for example, a scaled magnitude of the measured value 114, providing a simple calculation, which advantageously may be easily checked by a user of the fabrication tool 100. Alternately, computation of the deposition estimate parameter may involve a ratio of one of the measured values 114 taken at one time to another of the measured values 114 taken at a different time, providing a deposition estimate parameter which may advantageously be more consistent. Computation of the deposition estimate parameter may also involve measured values of other physical signals, which may advantageously provide a more reliable estimate of deposition in the process chamber 102. The process controller 108 determines when the deposition estimate parameter meets a minimum deposition criterion. The minimum deposition criterion may be established by the user of the fabrication tool 100 to avoid unnecessary in-situ cleans of the process chamber 102, or to balance particulate contamination due to primary deposition from production processes in the process chamber 102 with particulate contamination from secondary deposition from in-situ cleans of the process chamber 102. In one version of the instant example, the minimum deposition criterion may correspond to substantially no detectable deposition. In another version, the minimum deposition criterion may correspond to a detectable amount of deposition, but not enough to warrant an in-situ clean. When the result of the determination by the process controller 108 is TRUE, the process controller 108 terminates the smart in-situ chamber clean without further cleaning of the process chamber 102 so as to avoid unnecessary secondary deposition. When the result of the determination by the process controller 108 is FALSE, the process controller 108 continues the smart in-situ chamber clean with an in-situ cleaning of the process chamber 102.

Referring to FIG. 1B, in the instant example, the result of the determination by the process controller 108 is TRUE, and the process controller 108 terminates the smart in-situ chamber clean without further cleaning of the process chamber 102, as depicted in FIG. 1B by an absence of the initial plasma 112 of FIG. 1A. Secondary deposition of unwanted deposited material in the process chamber 102 from in-situ cleaning is avoided. The dummy wafer 110 is subsequently removed.

Referring to FIG. 1C, a production wafer 122 containing the microelectronic device 124 and other instances of similar microelectronic devices is placed in the fabrication tool 100 on the wafer chuck 104. Reactant gas, depicted in FIG. 1C as tetraethyl orthosilicate (TEOS), is flowed into the process chamber 102. A deposition plasma 126 is formed from the reactant gas over the microelectronic device 124 on the production wafer 122, resulting in deposition of silicon dioxide on the microelectronic device 124. In other versions of the instant example, the reactant gas may comprise bis(tertiary-butyl-amino) silane (BTBAS) to deposit silicon nitride on the microelectronic device 124. In further versions, other reactant gases may be used to deposit other materials on the microelectronic device 124. In yet other versions, the reactant gases may be etchants and an etch plasma may be formed over the production wafer 122 so as to remove material from the microelectronic device 124. Terminating the smart in-situ chamber clean without further cleaning of the process chamber 102 as described in reference to FIG. 1B may advantageously reduce particulate contamination on the production wafer 122 from secondary deposition formed by in-situ cleaning.

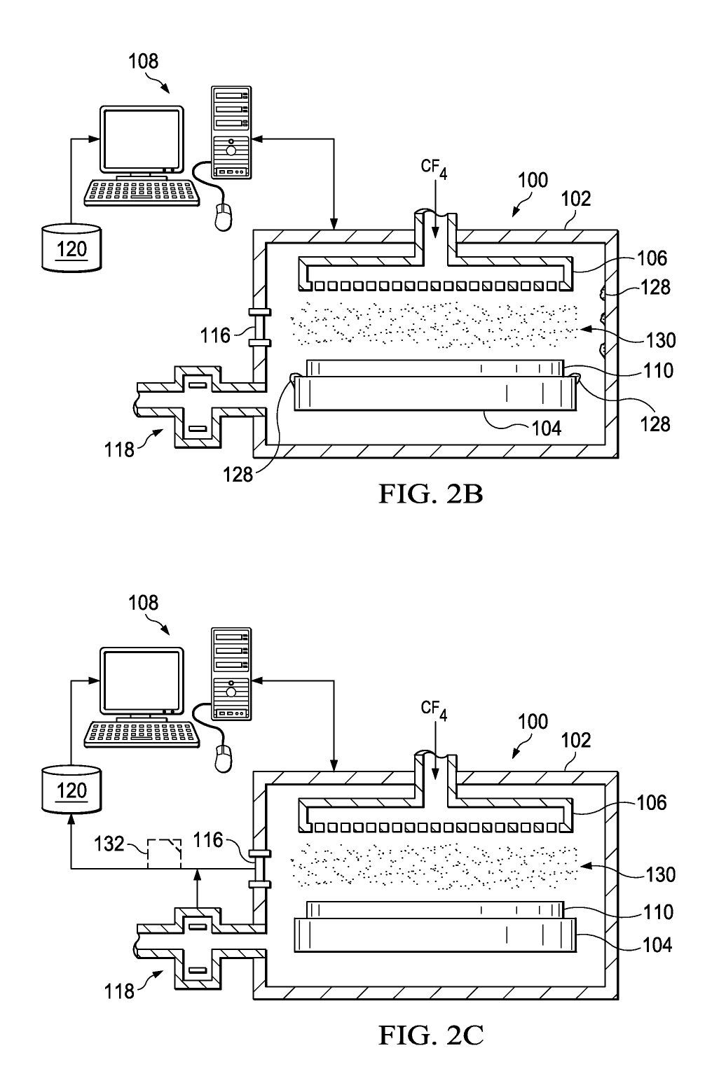

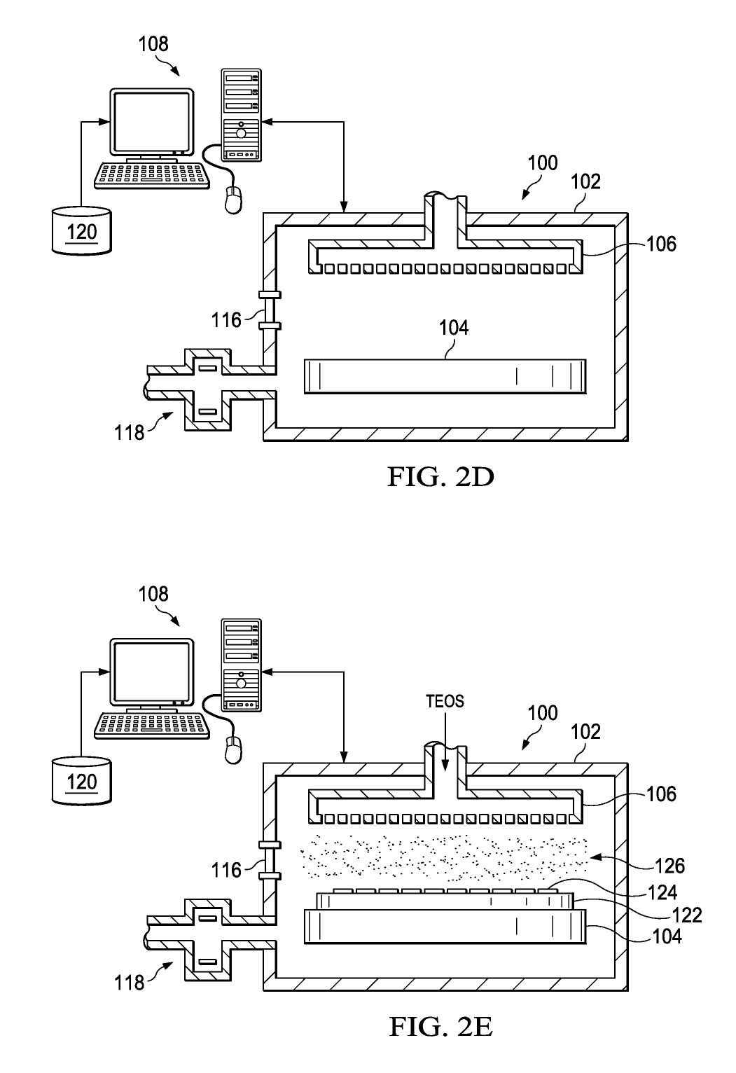

FIG. 2A through FIG. 2E are views of the fabrication tool of FIG. 1A through FIG. 1C, depicted in successive stages of another example fabrication sequence used for formation of the microelectronic device. Referring to FIG. 2A, first reactant gas, depicted in FIG. 2A as CF4, is flowed to the plasma region over the dummy wafer 110. The initial check for deposition, described in reference to FIG. 1A, is performed. Another initial plasma 112 is formed from the reactant gas over the dummy wafer 110. In the instant example, unwanted deposited material 128, deposited by previous processing, is present in the process chamber 102. The unwanted deposited material 128 may undesirably interfere with production processes in the fabrication tool 100, and so is advantageously removed before processing production wafers. A new measured value 114 of the first physical signal is obtained. The new measured value 114 differs from the measured value 114 of FIG. 1A due to the presence of the unwanted deposited material 128. The new measured value 114 of the first physical signal is stored in the memory unit 120.

The new measured value 114 of the first physical signal is retrieved from the memory unit 120 and transferred to the process controller 108. Additional new measured values 114 of the first physical signal or other physical signals, if stored in the memory unit 120, may also be retrieved and transferred to the process controller 108. The process controller 108 uses the retrieved new measured values 114 to compute the deposition estimate parameter, and subsequently determines when the deposition estimate parameter meets the minimum deposition criterion.

Referring to FIG. 2B, in the instant example, the result of the determination by the process controller 108 is FALSE. The process controller 108 initiates an in-situ clean process by flowing a second reactant gas, for example a fluorinated gas, depicted in FIG. 2B as CF4, to the plasma region over the dummy wafer 110. A cleaning plasma 130 is formed from the second reactant gas over the dummy wafer 110. In one version of the instant example, the second reactant gas is the same as the first reactant gas of FIG. 2A and FIG. 1A, and the cleaning plasma 130 is a continuation of the initial plasma 112 of FIG. 2A. Continuing the initial plasma 112 as the cleaning plasma 130 may advantageously provide a simpler smart in-situ chamber clean process. In another version, the cleaning plasma 130 is a separate plasma from the initial plasma 112. For example, the second reactant gas may be different from the first reactant gas, or power levels of the cleaning plasma 130 may be different from power levels of the initial plasma 112. Having the cleaning plasma 130 separate from the initial plasma 112 may advantageously allow optimization of each plasma for its respective purpose, that is providing a clear first physical signal and removing the unwanted deposited material 128, respectively. The cleaning plasma 130 begins to remove the unwanted deposited material 128 in the process chamber 102.

Referring to FIG. 2C, the cleaning plasma 130 continues to remove the unwanted deposited material 128 of FIG. 2B. In one version of the instant example, the cleaning plasma 130 may be continued for a pre-determined time, selected to remove a sufficient amount, possibly all, of the unwanted deposited material 128. In another version, the cleaning plasma 130 may be continued until an endpoint condition is met. For example, a measured value 132 of a second physical signal may be obtained, possibly as described with respect to the measured value 114 of the first physical signal of FIG, 2A. The second physical signal may be the same physical signal as the first physical signal, or may be different. Repeated measured values 132 of the second physical signal may be obtained. The measured value 132 may be stored in the memory unit 120, and retrieved by the process controller 108 which subsequently determines when to terminate the cleaning plasma 130. Alternatively, the measured value 132 may be used by a separate endpointing instrument which determines when to terminate the cleaning plasma 130.

Referring to FIG. 2D, a sufficient amount, possibly all, of the unwanted deposited material 128 of FIG. 2A has been removed from the process chamber 102. The cleaning plasma 130 of FIG. 2C is terminated, and the dummy wafer 110 of FIG. 2C is removed from the process chamber.

Referring to FIG. 2E, the production wafer 122 containing the microelectronic device 124 and other instances of similar microelectronic devices is placed in the fabrication tool 100 on the wafer chuck 104. The production wafer 122 is processed in the fabrication tool 100 as described in reference to FIG. 1C. Continuing the smart in-situ chamber clean with the cleaning of the process chamber 102 as described in reference to FIG. 2B through FIG. 2D may advantageously reduce particulate contamination on the production wafer 122 from the unwanted deposited material 128 of FIG. 2A.

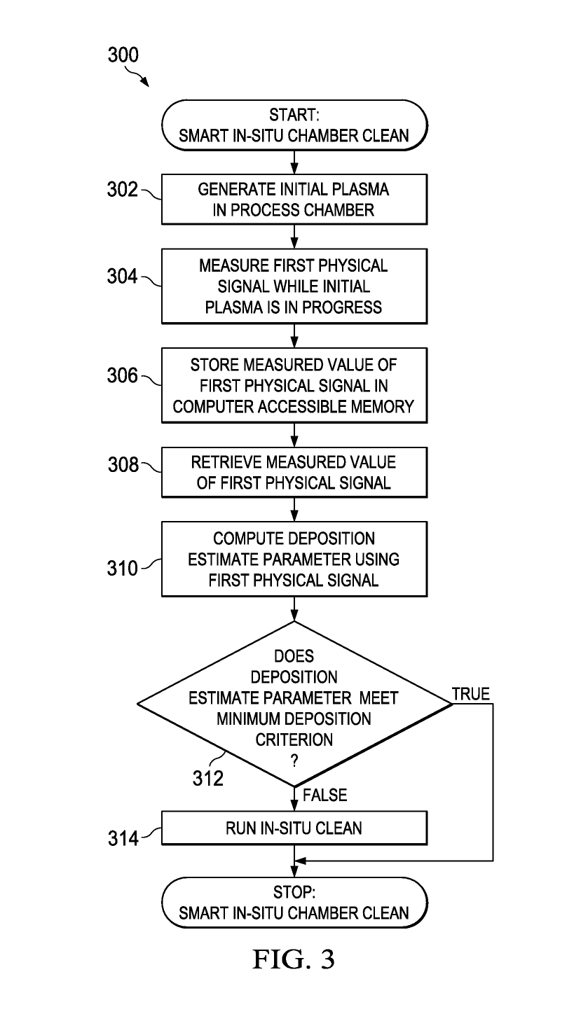

FIG. 3 is a flowchart of the smart in-situ chamber clean process. Referenced elements are found in FIG. 1A through FIG. 2E. The smart in-situ chamber clean process 300 starts with step 302: generate an initial plasma in the process chamber 102. The initial plasma 112 may be generated as described in reference to FIG. 1A.

The smart in-situ chamber clean process 300 continues with step 304: measure a first physical signal while the initial plasma is in progress, to provide a measured value 114 of the first physical signal. Multiple measurements of the first physical signal may be measured at multiple times, and additional physical signals may also be measured.

The smart in-situ chamber clean process 300 continues with step 306: store the measured value 114 in the memory unit 120. If multiple measured values 114 have been obtained, they are all stored in the memory unit 120. Measured values of other physical signals are also stored in the memory unit 120.

The smart in-situ chamber clean process 300 continues with step 308: retrieve the measured value 114, and other measured values 114 if present, from the memory unit 120. The measured values 114 are transferred to the process controller 108.

The smart in-situ chamber clean process 300 continues with step 310: compute the deposition estimate parameter, using the measured values 114, by the process controller 108. Computation of the deposition estimate parameter is described in reference to FIG. 1A. The deposition estimate parameter provides a value of how much unwanted deposited material exists in the process chamber 102.

The smart in-situ chamber clean process 300 continues with step 312: determine when the deposition estimate parameter meets the minimum deposition criterion. The minimum deposition criterion may be established by the user of the fabrication tool 100 as described in reference to FIG. 1A.

When the result of the determination is FALSE, that is, the deposition estimate parameter does not meet the minimum deposition criterion, indicating the amount of unwanted deposited material in the process chamber 102 is sufficient to warrant an in-situ clean, the smart in-situ chamber clean process 300 continues with step 314: run an in-situ clean on the process chamber 102 as described in reference to FIG. 2B through FIG. 2D. After the in-situ clean on the process chamber 102 is completed, the smart in-situ chamber clean process 300 ends.

When the result of the determination is TRUE, that is, the deposition estimate parameter meets the minimum deposition criterion, indicating the amount of unwanted deposited material in the process chamber 102 is less than an amount requiring an in-situ clean, the smart in-situ chamber clean process 300 ends without running the in-situ clean.

While various embodiments of the present invention have been described above, it should be understood that they have been presented by way of example only and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

What is claimed is:

1. A method of forming a microelectronic device, comprising the steps:
performing a smart in-situ chamber clean, comprising the steps:
flowing a first reactant gas into a process chamber of a fabrication tool;
forming an initial plasma from the first reactant gas in the process chamber;
obtaining a measured value of a first physical signal while the initial plasma is in progress;
storing the measured value in a storage unit;
retrieving the measured value from the storage unit;
transferring the measured value to a process controller coupled to the fabrication tool;
computing a deposition estimate parameter by the process controller using the measured value;
determining when the deposition estimate parameter meets a minimum deposition criterion;
when the deposition estimate parameter does not meet the minimum deposition criterion, then performing an in-situ clean of the process chamber, comprising flowing a second reactant gas into the process chamber and forming a cleaning plasma from the second reactant gas; and
when the deposition estimate parameter meets the minimum deposition criterion, then terminating the smart in-situ chamber clean without performing the in-situ clean of the process chamber; and
subsequently processing the microelectronic device in the process chamber.

2. The method of claim 1, wherein the fabrication tool is a thin film plasma deposition tool.

3. The method of claim 1, wherein the fabrication tool is a plasma etch tool.

4. The method of claim 1, wherein the first physical signal is an optical emission signal.

5. The method of claim 1, wherein the first physical signal is an infrared absorption signal.

6. The method of claim 1, wherein the first physical signal is a residual gas analysis signal.

7. The method of claim 1, wherein the first physical signal is generated in the initial plasma.

8. The method of claim 1, wherein the first physical signal is generated in a downstream generator.

9. The method of claim 1, wherein computation of the deposition estimate parameter involves a scaled magnitude of the measured value.

10. The method of claim 1, comprising obtaining additional measured values of the first physical signal while the initial plasma is in progress.

11. The method of claim 10, wherein computation of the deposition estimate parameter involves a ratio of the measured value taken at one time to another measured value taken at a different time.

12. The method of claim 11, comprising obtaining measured values of a second physical signal while the initial plasma is in progress, and wherein computation of the deposition estimate parameter involves a ratio of a first measured value of the second physical signal taken at one time to a second measured value of the second physical signal taken at a different time

13. The method of claim 1, wherein the second reactant gas is the same as the first reactant gas.

14. The method of claim 1, wherein the cleaning plasma is a continuation of the initial plasma.

15. The method of claim 1, wherein performing the in-situ clean of the process chamber comprises the steps:
obtaining a measured value of a second physical signal while the cleaning plasma is in progress; and
terminating the cleaning plasma at a time based on the measured value of the second physical signal.

16. The method of claim 15, wherein the second physical signal is the same as the first physical signal.

17. The method of claim 15, wherein the second physical signal is different from the first physical signal.

18. The method of claim 1, wherein the cleaning plasma is run for a pre-determined time.

19. A method of forming a microelectronic device, comprising the steps:
performing a first smart in-situ chamber clean, comprising the steps:
flowing a first reactant gas into a process chamber of a fabrication tool;
forming a first initial plasma from the first reactant gas in the process chamber;
obtaining a first measured value of a first physical signal while the first initial plasma is in progress;
storing the first measured value in a storage unit;
retrieving the first measured value from the storage unit;
transferring the first measured value to a process controller coupled to the fabrication tool;
computing a first deposition estimate parameter by the process controller using the first measured value;
determining when the first deposition estimate parameter meets a minimum deposition criterion;
subsequently performing an in-situ clean of the process chamber; and
terminating the first smart in-situ chamber clean;
performing a second smart in-situ chamber clean, comprising the steps:
flowing the first reactant gas into the process chamber of the fabrication tool;
forming a second initial plasma from the first reactant gas in the process chamber;
obtaining a second measured value of the first physical signal while the second initial plasma is in progress;
storing the second measured value in the storage unit;
retrieving the second measured value from the storage unit;
transferring the second measured value to the process controller;
computing a second deposition estimate parameter by the process controller using the second measured value;
determining when the second deposition estimate parameter meets the minimum deposition criterion; and
subsequently terminating the second smart in-situ chamber clean without performing an in-situ clean of the process chamber; and
subsequently processing the microelectronic device in the process chamber.

20. A method of forming a microelectronic device, comprising the steps:
performing a smart in-situ chamber clean, comprising the steps:
flowing a fluorinated gas into a process chamber of a fabrication tool;
forming an initial plasma from the fluorinated gas in the process chamber;
obtaining multiple measured values of an optical emission signal while the initial plasma is in progress;
storing the measured values in a storage unit;
retrieving the measured values from the storage unit;
transferring the measured values to a process controller coupled to the fabrication tool;
computing a deposition estimate parameter by the process controller using the measured values, wherein computing the deposition estimate parameter involves a ratio of two of the measured values;
determining when the deposition estimate parameter meets a minimum deposition criterion;
when the deposition estimate parameter does not meet the minimum deposition criterion, then performing an in-situ clean of the process chamber, comprising the steps:
continuing flowing the fluorinated gas into the process chamber and continuing the initial plasma as a cleaning plasma;
obtaining additional measured values of the optical emission signal while the cleaning plasma is in progress; and
terminating the cleaning plasma at a time based on the measured values of the optical emission signal; and
when the deposition estimate parameter meets the minimum deposition criterion, then terminating the smart in-situ chamber clean without performing the in-situ clean of the process chamber; and
subsequently processing the microelectronic device in the process chamber.
